(19) United States
(12) Patent Application Publication
(10) Pub. No.: US 2026/0255714 A1
(43) Pub. Date: Aug. 27, 2026

(54) HYBRID BOND DIE SEAL AND CRACK STOP STRUCTURES

(71) Applicant: SEMICONDUCTOR COMPONENTS INDUSTRIES, LLC, Scottsdale, AZ (US)

(72) Inventors: Jeffrey Peter GAMBINO, Gresham, OR (US); James Joseph STEFFES, Poughkeepsie, NY (US); John Michael MCGLONE, Portland, OR (US); Jon Patrick DALEY, Boise, ID (US); Swarnal BORTHAKUR, Boise, ID (US)

(73) Assignee: SEMICONDUCTOR COMPONENTS INDUSTRIES, LLC, Scottsdale, AZ (US)

(21) Appl. No.: 19/061,354

(22) Filed: Feb. 24, 2025

(51) Int. Cl. H10F 39/00

(52) U.S. Cl. CPC H10F 39/811; H10F 39/809

(57) ABSTRACT

A semiconductor device is disclosed. The semiconductor device includes a first die and a second die. The semiconductor device also includes a hybrid bond layer bonding the first die and the second die. The hybrid bond layer includes a plurality of hybrid bonds coupling internal circuitry of the first die to internal circuitry of the second die, a hybrid-bond die seal surrounding at least in part the plurality of hybrid bonds, and a plurality of hybrid-bond crack stops located around a perimeter of the semiconductor device between the hybrid-bond die seal and a device edge.

### TECHNICAL FIELD

The disclosure relates generally to imaging systems, and particularly to a hybrid bonding interface between stacked semiconductor wafers used to form an imaging system.

### BACKGROUND

Modern electronic devices such as cameras, computing systems, and vehicle imaging systems, often use image sensors. Image sensors may include two or more semiconductor dies bonded together. For example, an image sensor may be manufactured by bonding a first wafer including a first plurality of die, each with an image pixel array, to a second wafer including an second plurality of die with corresponding image processing circuitry. After bonding, the multi-wafer stack may be diced to separate the individual image sensor devices. During manufacture, the two (or more) wafers may be bonded together with conductive contacts, also referred to as hybrid bonds, on the bonding surfaces of both wafers. The conductive contacts may provide electrical connection between the circuits in the respective dies. Good connection requires that the hybrid bond contacts are sufficiently aligned, and that the hybrid bond contacts are level to provide good contact for adhesion of the two wafers.

The inventors of embodiments of the present disclosure have recognized that imperfections at the hybrid bond interface may result in die-to-die delamination and/or failures in electrical connections. The inventors of embodiments of the present disclosure have also recognized that such delamination or failures in electrical connections may cause product failure. Embodiments of the present disclosure may address one or more of these challenges.

### BRIEF DESCRIPTION OF THE DRAWINGS

A more complete understanding of the present embodiments may be acquired by referring to the following description taken in conjunction with the accompanying drawings, in which like reference numbers indicate like features.

FIG. 1 illustrates a top view of a multi-wafer stack in accordance with embodiments of the present disclosure.

FIG. 2A illustrates a side cross-section view of a multi-die semiconductor device in accordance with embodiments of the present disclosure.

FIG. 2B illustrates a top cross-section view of a multi-die semiconductor device in accordance with embodiments of the present disclosure.

FIG. 3 illustrates a top cross-section view of a multi-die semiconductor device in accordance with embodiments of the present disclosure.

FIG. 4 illustrates a top cross-section view of a multi-die semiconductor device in accordance with embodiments of the present disclosure.

FIG. 5 illustrates a top cross-section view of a multi-die semiconductor device in accordance with embodiments of the present disclosure.

FIG. 6 illustrates a top cross-section view of a multi-die semiconductor device in accordance with embodiments of the present disclosure.

FIG. 7 illustrates a top cross-section view of a multi-die semiconductor device in accordance with embodiments of the present disclosure.

FIG. 8A illustrates a side cross-section view of a multi-die semiconductor device in accordance with embodiments of the present disclosure.

FIG. 8B illustrates a top cross-section view of a multi-die semiconductor device in accordance with embodiments of the present disclosure.

FIG. 9A illustrates a side cross-section view of a multi-die semiconductor device in accordance with embodiments of the present disclosure.

FIG. 9B illustrates a top cross-section view of a multi-die semiconductor device in accordance with embodiments of the present disclosure.

FIG. 10A illustrates a side cross-section view of a multi-die semiconductor device in accordance with embodiments of the present disclosure.

FIG. 10B illustrates a top cross-section view of a multi-die semiconductor device in accordance with embodiments of the present disclosure.

FIGS. 11A-11C illustrate cross-section views of a multi-die stack in accordance with embodiments of the present disclosure.

### DETAILED DESCRIPTION

Details of one or more embodiments are set forth in the description below and the accompanying drawings. Other features will be apparent from the description, drawings, and from the claims. The embodiments disclosed should not be interpreted, or otherwise used, as limiting the scope of the disclosure, including the claims. In addition, one skilled in the art understands that the following description has broad application, and the discussion of any embodiment is meant to be exemplary of that embodiment, and not intended to intimate that the scope of the disclosure, including the claims, is limited to that embodiment.

Various terms are used to refer to particular system components. Different companies may refer to a component by different names, and this disclosure does not intend to distinguish between components that differ in name but not form and function. In the following discussion and in the claims, the terms “including” and “comprising” are used in an open-ended fashion, and thus should be interpreted to mean “including, but not limited to.” Also, the term “couple” or “coupled” is intended to mean either an indirect or direct connection. Thus, if a first device couples to, or is coupled to, a second device, that connection between the first device and the second device may be through a direct connection or through an indirect connection via other devices and connections.

Imaging systems may include image sensors that sense light by converting impinging photons of light into pairs of electrons and holes that are integrated or collected in pixel photodiodes within the sensor array. After completion of an integration cycle, collected charge may be converted into a voltage, which may be supplied to the output terminals of the sensor. In complementary metal-oxide semiconductor (CMOS) image sensors, the charge to voltage conversion may be accomplished directly in the pixels themselves and the analog pixel voltage may be transferred to the output terminals through various pixel addressing and scanning schemes. The analog pixel voltage can also be later converted on-chip to a digital equivalent and processed in the digital domain.

In other image sensing applications, a photodiode may be implemented with a single-photon avalanche diode (SPAD). In SPAD-based devices, the photon detection principle is different than in CMOS image sensors. The single-photon avalanche diode may be biased slightly above its reverse breakdown voltage, and when an incident photon generates an electron and hole pair, the electron or hole carrier may drift to the multiplication region where it may initiate an avalanche breakdown with additional carriers being generated. The avalanche multiplication may produce a current signal that may be detected by readout circuitry associated with the single-photon avalanche diode. The avalanche process may subsequently be stopped or quenched by lowering the bias voltage below or equal to the reverse breakdown voltage of the diode. Each single-photon avalanche diode may therefore include a passive and/or active quenching circuit for quenching the avalanche by lowering the bias voltage. SPAD-based devices may be used in multiple ways. For example, in low light level applications, the arriving photons may simply be counted. As another example, SPAD-based devices may be used to measure photon time-of-flight (ToF) from a synchronized light source to a scene object point and back to the sensor, which may be used to obtain a three-dimensional image of the scene.

For both CMOS image sensors, and SPAD-based image sensors, the image sensor may include two or more semiconductor die bonded together. For example, during manufacturing, a first wafer that includes a first plurality of die may be bonded to a second wafter including a corresponding second plurality of die. The first plurality of die of the first wafer may each include, for example, an image pixel array. The second plurality of die of the second wafter may each include, for example, image processing circuitry configured to sample and/or process image signals from a corresponding image pixel array. After bonding, the multi-wafer stack may be diced to separate the multiple instances of the image sensor device formed by the respective wafers.

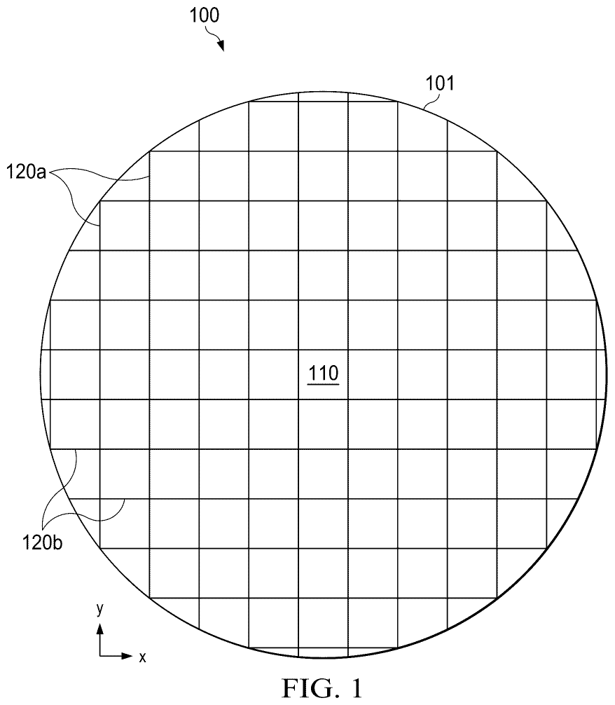

FIG. 1 illustrates a top view of multi-wafer stack 100 in accordance with embodiments of the present disclosure. Multi-wafer stack 100 may include a first wafer 101 bonded to an underlying second wafer (not shown in the top view of FIG. 1). First wafer 101 may include a plurality of first die 110 arranged in an array. The underlying second wafer may include a plurality of second die arranged in a corresponding array, with each second die bonded to the corresponding first die. Each instance of a first die 110 and the corresponding second die may form a multi-die semiconductor device. The plurality of first die 110 of first wafer 101 will not be physically separated from each other until after dicing. Likewise, the plurality of second die of the second wafer will not be separated from each other until after dicing. Nonetheless, for the purposes of the present disclosure, the term die may refer to either a pre-diced area of a wafer or a separated die post-dicing.

As shown in FIG. 1, multi-wafer stack 100 may also include scribe lanes 120a and scribe lanes 120b. Scribe lanes 120a may run parallel to the y-axis. Scribe lanes 120b may be orthogonal to the scribe lanes 120a, and may run parallel to the x-axis. During dicing, multi-wafer stack 100 may be cut along and/or within scribe lanes 120a and scribe lanes 120b to separate different instances of the multi-die semiconductor device from each other. Although FIG. 1 illustrates a given number of instances of first die 110 arranged in an array, multi-wafer stack 100 may be arranged with any suitable number of instances of first die 110 and corresponding underlying second die, separated by any suitable number of scribe lanes 120a and 120b, depending on the area of the multi-wafer stack and the area of the first die 110 and corresponding second die for a given application.

The dicing process may introduce physical stress and/or cracking along the edge of the respective first and second bonded dies. Such cracking may create a susceptibility to contaminants from the outside environment. As described in detail below, hybrid-bond die seals and/or hybrid-bond crack stops included in embodiments herein may provide the multi-die semiconductor device with improved reliability against delamination and/or contamination associated with cracking due to physical stresses incurred by the semiconductor device during, for example, the dicing process.

Embodiments described herein may include a hybrid bond layer that bonds a first die and a second die. In some embodiments, the hybrid bond layer may include a plurality of hybrid bonds coupling internal circuitry of a first die to internal circuitry of a second die. The hybrid bond layer may further include a hybrid-bond die seal surrounding at least in part the plurality of hybrid bonds. For example, the hybrid-bond die seal may form a ring surrounding the plurality of hybrid bonds.

The hybrid bond layer may also include a plurality of hybrid-bond crack stops located around a perimeter of the semiconductor device. In some embodiments, the plurality of hybrid-bond crack stops may be arranged in multiple rows, with each of the multiple rows forming a ring along a perimeter of the semiconductor device surrounding the plurality of hybrid bonds. And in some embodiments, the plurality of hybrid-bond crack stops may be located around a perimeter of the semiconductor device between the hybrid-bond die seal and a device edge. The hybrid-bond die seal and the hybrid-bond crack stops may provide the multi-die semiconductor device with improved reliability against delamination and/or contamination associated with cracking due to physical stresses incurred, for example, during the dicing process.

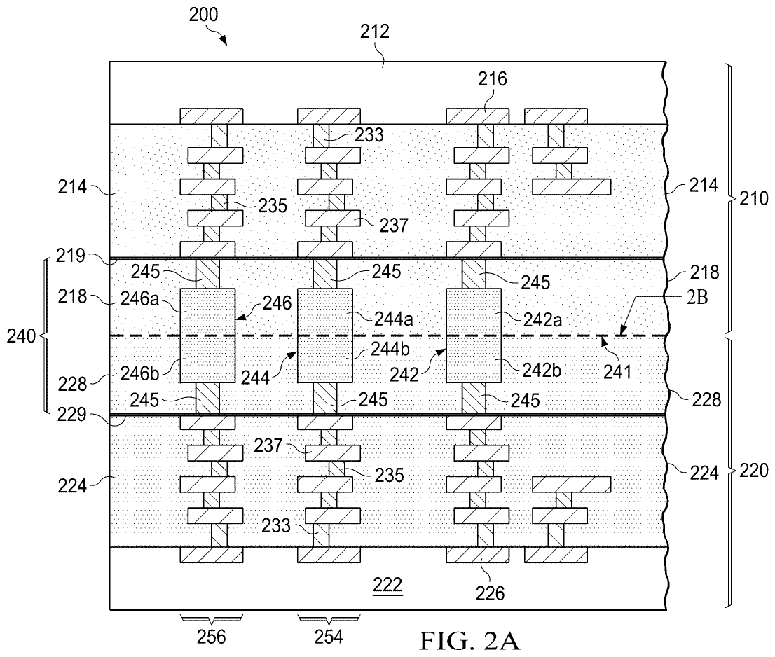

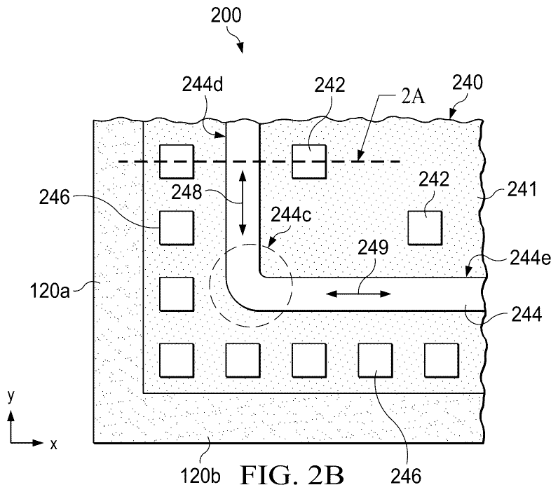

FIG. 2A illustrates a side cross-section view of multi-die semiconductor device 200 in accordance with embodiments of the present disclosure. Specifically, FIG. 2A illustrates a side cross-section view of multi-die semiconductor device 200 along cutline 2A illustrated in FIG. 2B. FIG. 2B illustrates a top cross-section view of multi-die semiconductor device 200 in accordance with embodiments of the present disclosure. Specifically, FIG. 2B illustrates a top cross-section view of multi-die semiconductor device 200 along cutline 2B illustrated in FIG. 2A.

As shown in FIG. 2A, multi-die semiconductor device 200 may include first die 210, second die 220, and hybrid bond layer 240. In some embodiments, first die 210 may be a light-sensing die including, for example, an image pixel array in an interior area of the die. Thus, for the purposes of the present disclosure, first die 210 may also be referred to as a light-sensing die. Second die 220 may be a signal-processing die including, for example, image processing circuitry configured to sample, hold, and/or process image signals from the corresponding image pixel array in first die 210. Thus, for the purposes of the present disclosure, second die 220 may also be referred to as a signal-processing die. In such embodiments where first die 210 is a light-sensing die and second die 220 is a signal-processing die, multi-die semiconductor device 200 may also be referred to as an image sensor device.

First die 210 may include substrate 212 and dielectric layer 214. Substrate 212 may be formed by a semiconductor material. For example, substrate 212 may be a silicon substrate. Various active regions 216 within substrate 212 may be configured to form the internal circuitry of first die 210, such as transistors and/or photo-sensitive diodes. As shown in FIG. 2A, contacts 233 may couple the respective active regions 216 to patterns of a metal layer 237 within dielectric layer 214, which may in turn be coupled to further metal layers 237 within dielectric layer 214 by vias 235. In some embodiments, dielectric layer 214 may be formed by an oxide material, such as silicon dioxide. Although illustrated in FIG. 2A as a continuous material, dielectric layer 214 may be formed by multiple layers of an oxide material, for example silicon dioxide, added one at a time with corresponding layers of vias 235 and metal layers 237.

Contacts 233, metal layers 237, and vias 235 may be formed by an electrically conductive material, such as a metal or a metal alloy. For example, contacts 233, metal layers 237, and vias 235 may be formed by copper, aluminum, and/or an alloy of copper or aluminum. In some embodiments, contacts 233, metal layers 237, and vias 235 may include the same electrically conductive material as each other. And in other embodiments, one or more of contacts 233, metal layers 237, and vias 235 may be formed with a different electrically conductive materials relative to each other.

Second die 220 may include substrate 222 and dielectric layer 224. Substrate 222 may be formed by a semiconductor material. For example, substrate 222 may be a silicon substrate. Various active regions 226 within substrate 222 may be configured to form the internal circuitry of second die 220, such as transistors, capacitors, and/or other circuit components used for image processing. As shown in FIG. 2A, contacts 233 may couple the respective active regions 226 to patterns of a metal layer 237 within dielectric layer 224, which may in turn be coupled to further metal layers 237 within dielectric layer 224 by vias 235. In some embodiments, dielectric layer 224 may be formed by an oxide material, such as silicon dioxide. Although illustrated in FIG. 2A as a continuous material, dielectric layer 224 may be formed by multiple layers of an oxide material, for example silicon dioxide, added one at a time with corresponding layers of vias 235 and metal layers 237.

In some embodiments, multi-die semiconductor device 200 may also include protective layer 219 and/or protective layer 229. As shown in FIG. 2A, protective layer 219 may be formed at the border between dielectric layer 214 and dielectric layer 218. For example, protective layer 219 may be formed on the surface of first die 210 prior to the formation of dielectric layer 218. Similarly, protective layer 229 may be formed at the border between dielectric layer 224 and dielectric layer 228. For example, protective layer 229 may be formed on the surface of second die 220 prior to the formation of dielectric layer 228. In some embodiments, protective layer 219 and/or protective layer 229 may be formed by silicon nitride for example. The silicon nitride may provide a barrier that prevents contaminants, from within hybrid bond layer 240 for example, from entering into the respective dielectric layer 214 of first die 210 or the dielectric layer 224 of second die 220. As explained below with reference to FIG. 2A and FIG. 2B, a plurality of hybrid-bond crack stops 246 and hybrid-bond die seal 244 may further prevent cracking and/or contaminants from reaching an interior portion of hybrid bond layer 240. Thus, the plurality of hybrid-bond crack stops 246 and hybrid-bond die seal 244 may work in conjunction with protective layer 219 and/or protective layer 229 to protect the internal circuitry of first die 210 and second die 220 from cracking, contamination, and/or circuit failures resulting therefrom.

As shown in FIG. 2A, hybrid bond layer 240 may include portions of first die 210 and portions of second die 220. For example, to prepare first die 210 for bonding, a dielectric layer 218 may be added to the surface of first die 210. Contacts 245 and pads 242a, 244a, and 246a may be formed within dielectric layer 218. Contacts 245 may include or may be formed by a metal or a metal alloy. For example, contacts 245 may include or be formed by one or more of copper and aluminum, or alloys of copper and/or aluminum. Pads 242a, 244a, and 246a may include or may be formed with an electrically conductive material. In some embodiments, pads 242a, 244a, and 246a may include copper. Similarly, to prepare second die 220 for bonding, a dielectric layer 228 may be added to the surface of second die 220. Contacts 245 and pads 242b, 244b, and 246b may be formed within dielectric layer 228. Pads 242b, 244b, and 246b may include or may be formed with an electrically conductive material. In some embodiments, pads 242b, 244b, and 246b may include the same conductive material, such as copper, as pads 242a, 244a, and 246a.

During bonding, first die 210 and second die 220 may be aligned such that pads 242a and 242b align, pads 244a and 244b align, and pads 246a and 246b align. The two wafers are bonded at room temperature at which point the bond is formed between the dielectric layers 218 on either side, for example a silicon dioxide to silicon dioxide bond. A high-temperature anneal, may then be performed. The high-temperature anneal may be applied at between 150 degrees Celsius to 400 degrees Celsius when copper in the respective pairs of pads expands from both directions and fuses into one another. Such fusion may or may not be accompanied by copper grain growth. The dual bonding of both the oxide material at dielectric interface 241 and the conductive material of the respective pads may form the hybrid bond joining first die 210 to second die 220. For example, pads 242a and 242b may collectively form hybrid bond 242. Pads 244a and 244b may collectively form hybrid-bond die seal 244, described in further detail below with reference to FIG. 2B. Further, pads 246a and 246b may collectively form one of a plurality of hybrid-bond crack stops 246, also described in further detail below with reference to FIG. 2B.

FIG. 2B illustrates a top cross-section view of multi-die semiconductor device 200 along cutline BB illustrated in FIG. 2A. As shown in FIG. 2B, hybrid bond layer 240 may include a dielectric interface 241, a plurality of hybrid bonds 242, hybrid-bond die seal 244, and a plurality of hybrid-bond crack stops 246. For the sake of simplicity, FIG. 2B illustrates from a top view perspective the lower left corner of the hybrid bond layer 240 of multi-die semiconductor device 200 as abutted by scribe lane 120a and scribe lane 120b. The pattern of hybrid bonds 242, hybrid-bond die seal 244, and a plurality of hybrid-bond crack stops 246 may follow the entirety of the perimeter of hybrid bond layer 240, including all four corners and all four sides of multi-die semiconductor device 200.

As shown in FIG. 2B, hybrid bond layer 240 may include a plurality of hybrid bonds 242 in an interior area of hybrid bond layer 240. The plurality of hybrid bonds 242 may couple internal circuitry of the first die to internal circuitry of the second die. As described above with reference to FIG. 2A, hybrid bonds 242 may include or be formed by a metal or a metal alloy suitable to electrically couple the internal circuitry of the first die to the internal circuitry of the second die. For example, hybrid bonds 242 may include or be formed by one or more of copper and aluminum, or alloys of copper and/or aluminum.

As also shown in FIG. 2B, hybrid bond layer 240 may include hybrid-bond die seal 244. Hybrid-bond die seal 244 may surround at least in part, and from the top view perspective of FIG. 2B, the plurality of hybrid bonds 242. For example, hybrid-bond die seal 244 may form a ring surrounding the plurality of hybrid bonds 242. Hybrid-bond die seal 244 may include or be formed by a metal or a metal alloy. For example, hybrid-bond die seal 244 may include or be formed by one or more of copper and aluminum, or alloys of copper and/or aluminum. In some embodiments, hybrid-bond die seal 244 may include or be formed by the same metal or metal alloy as the plurality of hybrid bonds 242.

Hybrid-bond die seal 244 may in some embodiments include first linear portion 244d, second linear portion 244e, and joint 244c. As shown in FIG. 2B, first linear portion 244d may be disposed along a first axis 248, and second linear portion 244e may be disposed along a second axis 249 that is orthogonal to the first axis 248. Joint 244c may couple first linear portion 244d to second linear portion 244e. Moreover, in some embodiments, joint 244c may be curved. Although shown in FIG. 2B as continuously curved, semiconductor processing tools may sometimes require use of linear patterns. Thus, in some embodiments, the curvature of joint 244c may be implemented by a plurality of linear patterns connected in series in a gradual turning pattern to emulate a curve.

In some embodiments, hybrid bond layer 240 may also include a plurality of hybrid-bond crack stops 246 located around the perimeter of multi-die semiconductor device 200 between hybrid-bond die seal 244 and a device edge. For example, as shown in FIG. 2B, the plurality of hybrid-bond crack stops 246 may be disposed in a row around the perimeter of multi-die semiconductor device 200 to the outside of hybrid-bond die seal 244 relative to the die edge that will be formed during dicing when the multi-wafer stack is cut along scribe lanes 120a and 120b. Hybrid-bond crack stops 246 may include or be formed by a metal or a metal alloy. For example, hybrid-bond crack stops 246 may include or be formed by one or more of copper and aluminum, or alloys of copper and/or aluminum. In some embodiments, hybrid-bond crack stops 246 may include or be formed by the same metal or metal alloy as the plurality of hybrid bonds 242 and/or hybrid-bond die seal 244.

In some embodiments, each of the plurality of hybrid-bond crack stops 246 may have the same height and the same width as each of the plurality of hybrid bonds 242, along the bond plane shown by the x-axis and y-axis in FIG. 2B. Moreover, hybrid-bond crack stops 246 may be formed with the same minimum distances from each other as required for hybrid bonds 242. Thus, in some embodiments, the plurality of hybrid-bond crack stops 246 may have the same minimum pitch along the bond plane as the plurality of hybrid bonds 242.

The plurality of hybrid-bond crack stops 246 and the hybrid-bond die seal 244 may improve the reliability of multi-die semiconductor device 200. For example, hybrid-bond crack stops 246 may intercept cracks that form at the die edge, during dicing for example, and stop those cracks from proceeding inward along dielectric interface 241 to an interior area of hybrid bond layer 240 and multi-die semiconductor device 200 as a whole. Hybrid-bond die seal 244 may further aid in intercepting cracks from the die edge, as well as maintaining a seal that prevents outside contaminants from traveling through such cracks and reaching the interior area of hybrid bond layer 240 and multi-die semiconductor device 200 as a whole.

The shape of hybrid-bond die seal 244 may help achieve this benefit without significantly sacrificing the structural strength of the hybrid bond layer 240. As described above with reference to FIG. 2A, dielectric interface 241 may be formed by a bond between dielectric layer 218 of first die 210 and dielectric layer 228 of second die 220. The bond at dielectric interface 241 between dielectric layer 218 and dielectric layer 228 may provide mechanical strength to the overall bond between first die 210 and the second die 220. The shape of joint 244c may allow hybrid-bond die seal 244 to form a ring surrounding the plurality of hybrid bonds 242, but without causing excess hybrid-bond die-seal density at or around the corner areas of the ring. By limiting the hybrid-bond die-seal density at or around the corner areas of the ring formed by hybrid-bond die seal 244, the structural strength provided by dielectric interface 241 may be maintained, and delamination under physical stress may be avoided. The shape of hybrid-bond die seal 244, including the curvature of joint 244c for example, may thus prevent delamination that may otherwise occur under physical stress due to a loss of mechanical strength in a given area of hybrid bond layer 240 where the hybrid-bond die-seal density is greatest.

Referring back to the side cross-section view of FIG. 2A, hybrid-bond die seal 244 may form a portion of multi-die seal 254. As shown in FIG. 2A, multi-die seal 254 may extend from substrate 212 of first die 210 to substrate 222 of second die 220. For example, multi-die seal 254 may include various contacts 233, vias 235, metal layers 237, contacts 245, as well as hybrid-bond die seal 244, collectively forming a continuous barrier that extends from substrate 212 of first die 210 to substrate 222 of second die 220. In other embodiments, hybrid-bond die seal 244 may be implemented separately from die seals within first die 210 and second die 220. For example, in some embodiments, the instances of contacts 245 above and below hybrid-bond die seal 244 may be omitted, and hybrid-bond die seal 244 may thus be separate from above and below die seals within first die 210 and second die 220.

In some embodiments, at least one of the plurality of hybrid-bond crack stops 246 may form a portion of a multi-die crack stop 256. As shown in FIG. 2A, multi-die crack stop 256 may extend from substrate 212 of first die 210 to substrate 222 of second die 220. For example, multi-die crack stop 256 may include various contacts 233, vias 235, metal layers 237, contacts 245, as well as hybrid-bond crack stop 246, collectively forming a continuous crack-stop barrier that extends from substrate 212 of first die 210 to substrate 222 of second die 220. In other embodiments, hybrid-bond crack stop 246 may be implemented separately from crack stops within first die 210 and second die 220. For example, in some embodiments, the instances of contacts 245 above and below hybrid-bond crack stop 246 may be omitted, and hybrid-bond crack stop 246 may thus be separate from above and below crack stops within first die 210 and second die 220.

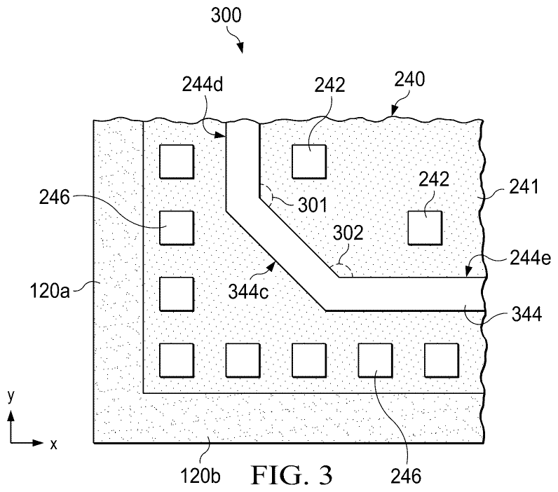

FIG. 3 illustrates a top cross-section view of multi-die semiconductor device 300 in accordance with embodiments of the present disclosure. Multi-die semiconductor device 300 may represent an alternative embodiment of multi-die semiconductor device 200 described above with reference to FIGS. 2A and 2B. For example, multi-die semiconductor device 300 may include similar features configured in a similar manner as multi-die semiconductor device 200, including the first die, the second die, hybrid bond layer 240, dielectric interface 241, the plurality of hybrid bonds 242, and the plurality of hybrid-bond crack stops 246.

As shown in FIG. 3, multi-die semiconductor device 300 may also include hybrid-bond die seal 344. Hybrid-bond die seal 344 may be configured in a similar manner as hybrid-bond die seal 244 described above with reference to FIG. 2A and FIG. 2B, but may have a joint 344c that linearly extends from the first linear portion 244d to the second linear portion 244e of hybrid-bond die seal 344. Joint 344c may form a first interior angle 301 with first linear portion 244d that is greater than 90 degrees. Joint 344c may also form a second interior angle 302 with second linear portion 244e that is greater than 90 degrees. Because both interior angles 301 and 302 are greater than 90 degrees, joint 344c may also be referred to as an obtuse joint that couples first linear portion 244d to second linear portion 244e.

Although FIG. 3 illustrates, from a top-view perspective, only a single corner of multi-die semiconductor device 300, the pattern of the linear portions and the joint of hybrid-bond die seal 344, and/or the pattern of hybrid-bond crack stops 246, may be repeated around all four sides and all four corners of multi-die semiconductor device 300. Thus, hybrid-bond die seal 344 may form a ring surrounding a plurality of hybrid bonds 242 located in the interior area of multi-die semiconductor device 300. Further, the plurality of hybrid-bond crack stops 246 may be located around a perimeter of multi-die semiconductor device 300 between hybrid-bond die seal 344 and a device edge.

The shape of joint 344c may allow hybrid-bond die seal 344 to form a ring surrounding the plurality of hybrid bonds 242, but without causing excess hybrid-bond die-seal density at or around the corner areas of the ring. By limiting the hybrid-bond die-seal density at or around the corner areas of the ring formed by hybrid-bond die seal 344, the structural strength provided by dielectric interface 241 may be maintained, and delamination under physical stress may be avoided.

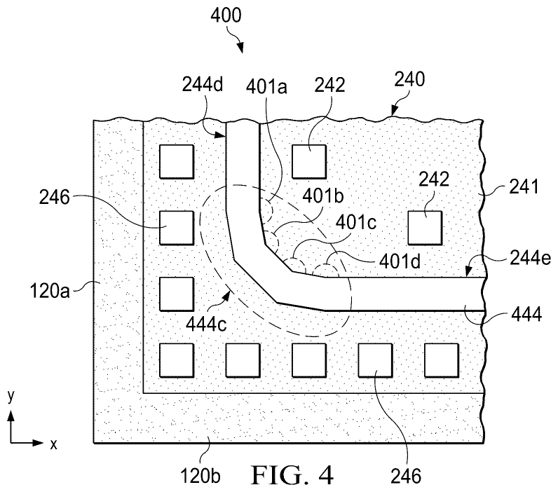

FIG. 4 illustrates a top cross-section view of multi-die semiconductor device 400 in accordance with embodiments of the present disclosure. Multi-die semiconductor device 400 may represent an alternative embodiment of multi-die semiconductor device 200 described above with reference to FIGS. 2A and 2B. For example, multi-die semiconductor device 400 may include similar features configured in a similar manner as multi-die semiconductor device 200, including the first die, the second die, hybrid bond layer 240, dielectric interface 241, the plurality of hybrid bonds 242, and the plurality of hybrid-bond crack stops 246.

As shown in FIG. 4, multi-die semiconductor device 400 may also include hybrid-bond die seal 444. Hybrid-bond die seal 444 may be configured in a similar manner as hybrid-bond die seal 244 described above with reference to FIG. 2A and FIG. 2B, but may have a joint 444c that includes a plurality of linear-joint portions coupled in series between first linear portion 244d and second linear portion 244e of hybrid-bond die seal 444. As shown in FIG. 4, each interior angle 401a, 401b, 401c, and 401d formed by first linear portion 244d, second linear portion 244e, and the plurality of linear-joint portions is greater than 90 degrees. Because each interior angle 401a, 401b, 401c, and 401d is greater than 90 degrees, joint 444c may also be referred to as an obtuse joint that couples first linear portion 244d to second linear portion 244e.

Although FIG. 4 illustrates, from a top-view perspective, only a single corner of multi-die semiconductor device 400, the pattern of the linear portions and the joint of hybrid-bond die seal 444, and/or the pattern of hybrid-bond crack stops 246, may be repeated around all four sides and all four corners of multi-die semiconductor device 400. Thus, hybrid-bond die seal 444 may form a ring surrounding a plurality of hybrid bonds 242 located in the interior area of multi-die semiconductor device 400. Further, the plurality of hybrid-bond crack stops 246 may be located around a perimeter of multi-die semiconductor device 400 between hybrid-bond die seal 444 and a device edge.

The shape of joint 444c may allow hybrid-bond die seal 444 to form a ring surrounding the plurality of hybrid bonds 242, but without causing excess hybrid-bond die-seal density at or around the corner areas of the ring. By limiting the hybrid-bond die-seal density at or around the corner areas of the ring formed by hybrid-bond die seal 444, the structural strength provided by dielectric interface 241 may be maintained, and delamination under physical stress may be avoided.

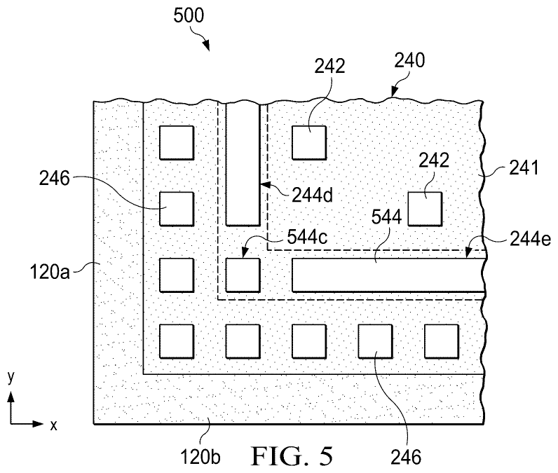

FIG. 5 illustrates a top cross-section view of multi-die semiconductor device 500 in accordance with embodiments of the present disclosure. Multi-die semiconductor device 500 may represent an alternative embodiment of multi-die semiconductor device 200 described above with reference to FIGS. 2A and 2B. For example, multi-die semiconductor device 500 may include similar features configured in a similar manner as multi-die semiconductor device 200, including the first die, the second die, hybrid bond layer 240, dielectric interface 241, the plurality of hybrid bonds 242, and the plurality of hybrid-bond crack stops 246.

As shown in FIG. 5, multi-die semiconductor device 500 may also include hybrid-bond die seal 544. Hybrid-bond die seal 544 may be configured in a similar manner as hybrid-bond die seal 244 described above with reference to FIG. 2A and FIG. 2B, but may have an island joint 544c located at a corner to first linear portion 244d and second linear portion 244e of hybrid-bond die seal 544.

Although FIG. 5 illustrates, from a top-view perspective, only a single corner of multi-die semiconductor device 500, the pattern of the linear portions and the joint of hybrid-bond die seal 544, and/or the pattern of hybrid-bond crack stops 246, may be repeated around all four sides and all four corners of multi-die semiconductor device 500. Thus, hybrid-bond die seal 544 may form a ring that surrounds at least in part a plurality of hybrid bonds 242 located in the interior area of multi-die semiconductor device 500. Further, the plurality of hybrid-bond crack stops 246 may be located around a perimeter of multi-die semiconductor device 500 between hybrid-bond die seal 544 and a device edge.

The configuration of island joint 544c may allow hybrid-bond die seal 544 to form a ring surrounding at least in part the plurality of hybrid bonds 242, but without causing excess hybrid-bond die-seal density at or around the corner areas of the ring. By limiting the hybrid-bond die-seal density at or around the corner areas of the ring formed by hybrid-bond die seal 544, the structural strength provided by dielectric interface 241 may be maintained, and delamination under physical stress may be avoided.

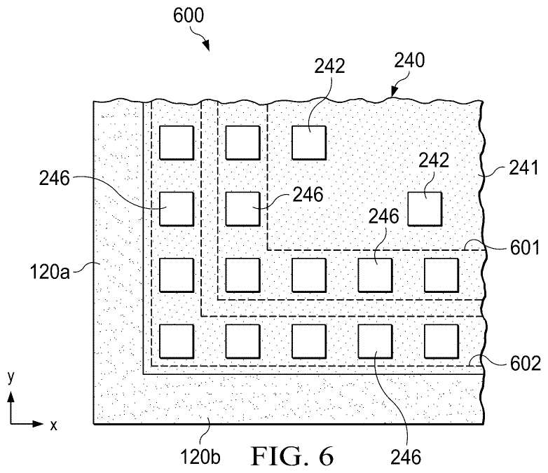

FIG. 6 illustrates a top cross-section view of multi-die semiconductor device 600 in accordance with embodiments of the present disclosure. Multi-die semiconductor device 600 may represent an alternative embodiment of multi-die semiconductor device 200 described above with reference to FIGS. 2A and 2B. For example, multi-die semiconductor device 600 may include similar features configured in a similar manner as multi-die semiconductor device 200, including the first die, the second die, hybrid bond layer 240, dielectric interface 241, the plurality of hybrid bonds 242, and a plurality of hybrid-bond crack stops 246.

In some embodiments, the plurality of hybrid-bond crack stops 246 of multi-die semiconductor device 600 may be arranged in multiple rows. For example, as shown in FIG. 6, the plurality of hybrid-bond crack stops 246 may be arranged in first row 601 and second row 602. Although FIG. 6 illustrates, from a top-view perspective, only a single corner of multi-die semiconductor device 600, the pattern of hybrid-bond crack stops 246 may be repeated around all four sides and all four corners of multi-die semiconductor device 600. Thus, each of the multiple rows, including for example first row 601 and second row 602, may form a ring along a perimeter of multi-die semiconductor device 600 surrounding the plurality of hybrid bonds 242.

The multiple rows of hybrid-bond crack stops 246 may protect the interior of multi-die semiconductor device 600 from cracking along the die edge that may occur during wafer dicing. The configuration of the plurality of hybrid-bond crack stops 246 may achieve this benefit without causing excess hybrid-bond density at or around the corner areas of multi-die semiconductor device 600. For example, as described above, the spacing between any two hybrid-bond crack stops 246 may have the same minimum pitch as required for the plurality of hybrid bonds 242. The density of the plurality of hybrid-bond crack stops 246 in any given area may thus be limited in a manner such that the structural strength provided by dielectric interface 241 may be maintained.

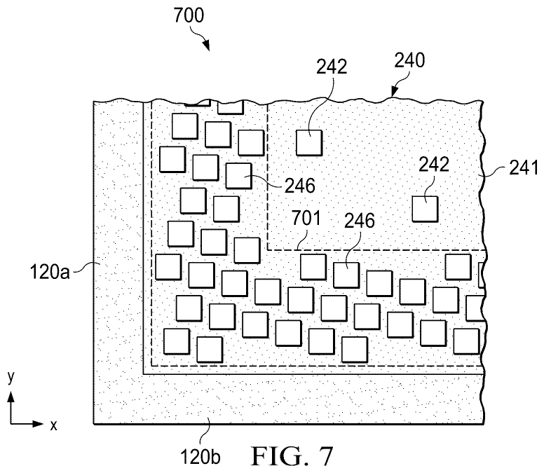

FIG. 7 illustrates a top cross-section view of multi-die semiconductor device 700 in accordance with embodiments of the present disclosure. Multi-die semiconductor device 700 may represent an alternative embodiment of multi-die semiconductor device 200 described above with reference to FIGS. 2A and 2B. For example, multi-die semiconductor device 700 may include similar features configured in a similar manner as multi-die semiconductor device 200, including the first die, the second die, hybrid bond layer 240, dielectric interface 241, the plurality of hybrid bonds 242 and a plurality of hybrid-bond crack stops 246.

In some embodiments, the plurality of hybrid-bond crack stops 246 of multi-die semiconductor device 700 may be arranged in multiple rows, each of the multiple rows forming a ring along a perimeter of multi-die semiconductor device 700 surrounding the plurality of hybrid bonds 242. For example, as shown in FIG. 7, the plurality of hybrid-bond crack stops 246 may be arranged in multiple rows within crack-stop area 701 following the perimeter of multi-die semiconductor device 700. Although FIG. 7 illustrates, from a top-view perspective, only a single corner of multi-die semiconductor device 700, the pattern of hybrid-bond crack stops 246 may be repeated around all four sides and all four corners of multi-die semiconductor device 700.

The multiple rows of hybrid-bond crack stops 246 may protect the interior of multi-die semiconductor device 700 from cracking along the die edge that may occur during wafer dicing when the multi-die stack is cut along scribe lanes 120a and 120b. For example, as shown in FIG. 7, the plurality of hybrid-bond crack stops 246 may be arranged within the multiple rows such that any single linear path in hybrid bond layer 240 from an edge of multi-die semiconductor device 700 to an interior of multi-die semiconductor device 700 is intercepted by at least one of the plurality of hybrid-bond crack stops 246.

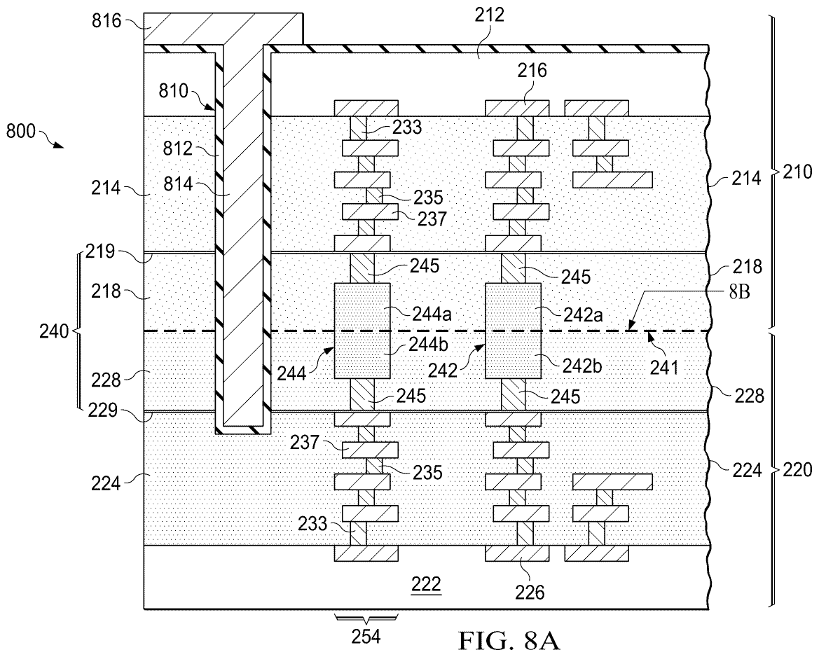

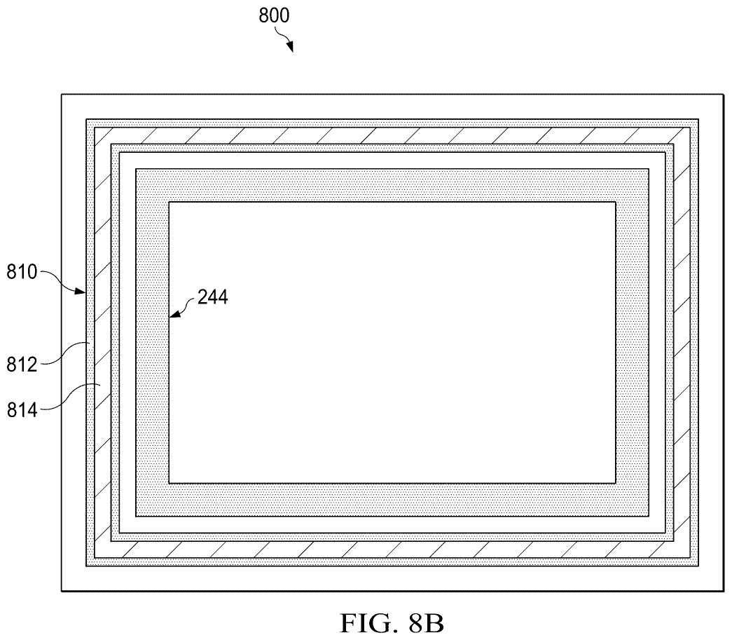

FIG. 8A illustrates a side cross-section view of multi-die semiconductor device 800 in accordance with embodiments of the present disclosure. Multi-die semiconductor device 800 may represent an alternative embodiment of multi-die semiconductor device 200 described above with reference to FIGS. 2A and 2B. For example, multi-die semiconductor device 800 may include similar features configured in a similar manner as multi-die semiconductor device 200, including the first die, the second die, hybrid bond layer 240, dielectric interface 241, the plurality of hybrid bonds 242, and a multi-die seal 254 including hybrid-bond die seal 244 surrounding an interior of multi-die semiconductor device 800. Although not shown in FIG. 8A, multi-die semiconductor device 800 may optionally include a plurality of hybrid-bond crack stops 246 located around a perimeter of multi-die semiconductor device 800.

Multi-die semiconductor device 800 may also include trench 810. As shown in FIG. 8A, trench 810 may extend from an upper surface of substrate 212, through substrate 212 of first die 210, through dielectric layer 214 of first die 210, through hybrid bond layer 240, and into dielectric layer 224 of second die 220. In some embodiments, the depth of trench 810 may be for example 9 μm and the width of trench 810 may be for example 0.9 μm. Other depths and widths for trench 810 may be utilized depending, for example, on the thickness of first die 210 and second die 220. Trench 810 may include trench liner 812 and trench filler 814. In some embodiments, trench liner 812 may include a high-K dielectric, such as one or more of hafnium oxide, aluminum oxide, and/or tantalum oxide. And in some embodiments, trench liner 812 may be formed by and/or include a nitride passivation film. Trench filler 814 may include a conductive material such as a metal or a metal alloy. For example, trench filler 814 may in some embodiments include one or more of copper, tungsten, and aluminum, and/or an alloy thereof.

Trench 810 may form a barrier that protects the interior of multi-die semiconductor device 800 from cracking that may occur along the die edge, and resulting contamination, due to physical stress that is incurred for example during wafer dicing when the multi-die stack is cut along the scribe lanes. Moreover, the trench 810 may be formed after the hybrid bonding process, thereby avoiding any interference with the strength and continuity of the hybrid bond between the first die 210 and the second die 220.

During manufacture of multi-die semiconductor device 800, first die 210 and second die 220 may be bonded as described above with reference to FIG. 2A. The substrate 212 of first die 210 may then be thinned to its final epitaxial thickness. A trench hole may then be etched through substrate 212 of first die 210, through dielectric layer 214 of first die 210, through hybrid bond layer 240, and into dielectric layer 224 of second die 220. In some embodiments, the trench holes may be formed using lithography and plasma etching. After the trench holes are formed, trench 810 may be formed by filling the trench holes. For example, the trench holes may optionally be first filled with trench liner 812. As shown in FIG. 8A, the passivating material used to form trench liner 812 may also be applied to the upper surface of first die 210, and may thus also passivate the upper surface of first die 210. The remainder of the trench hole may then be filled with trench filler 814. In some embodiments, trench filler 814 may be coupled to a back-side metal shield or a back-side metal grid, such as metal grid 816 shown in FIG. 8A.

FIG. 8B illustrates a top cross-section view of multi-die semiconductor device 800 in accordance with embodiments of the present disclosure. Specifically, FIG. 8B illustrates a top cross-section view of multi-die semiconductor device 800 along cutline 8B illustrated in FIG. 8A. FIG. 8B shows the relationship of the location of trench 810 relative to hybrid-bond die seal 244. For simplicity, FIG. 8B omits the plurality of hybrid bonds 242 located in the interior of multi-die semiconductor device 800 and surrounded by trench 810 and hybrid-bond die seal 244. As shown in FIG. 8B, trench 810 forms a ring located along a perimeter of multi-die semiconductor device 800. For example, trench 810 forms a ring located along a perimeter of multi-die semiconductor device 800 between hybrid-bond die seal 244 and the device edge.

Referring back to FIG. 8A, multi-die seal 254 may include hybrid-bond die seal 244 within hybrid bond layer 240, as well as various metal layers 237, vias 235, and contacts 233 extending in a continuous manner through first die 210 and thus forming a guard ring in first die 210. Thus, in addition to forming a ring that surrounds hybrid-bond die seal 244 in hybrid bond layer 240, trench 810 may form a ring that also surrounds a metal guard ring of first die 210. Trench 810 may also form a ring surrounding the internal circuitry of first die 210 formed at least in part by various active regions 216 within substrate 212 of first die 210.

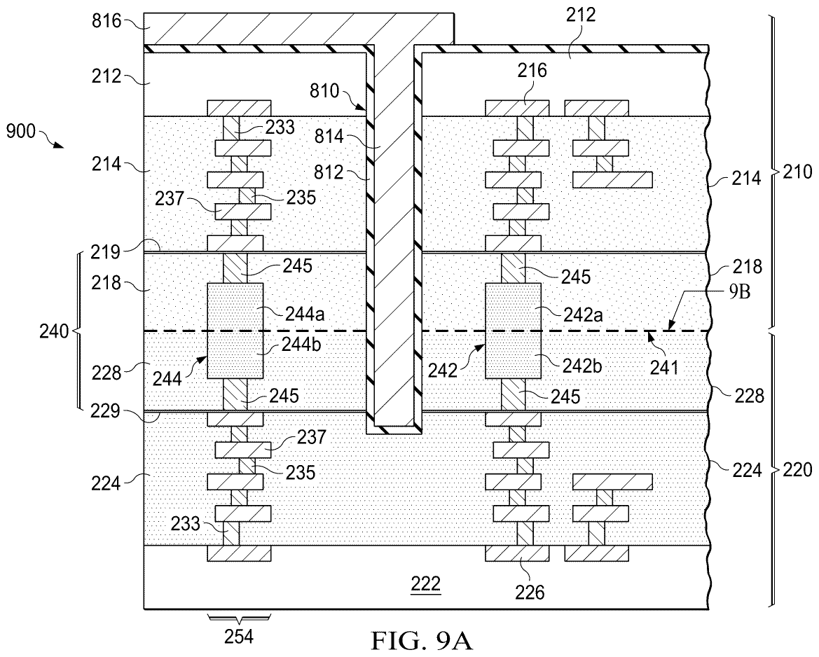

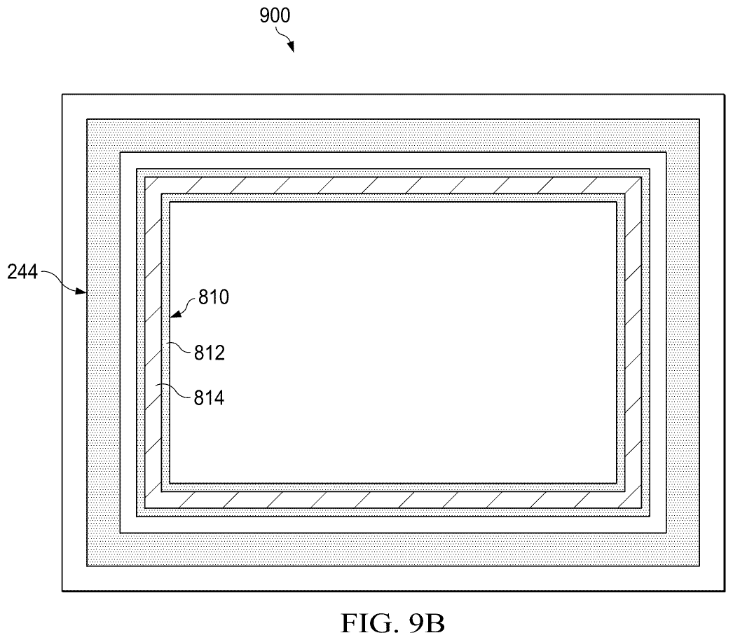

FIG. 9A illustrates a side cross-section view of multi-die semiconductor device 900 in accordance with embodiments of the present disclosure. Multi-die semiconductor device 900 may represent an alternative embodiment of multi-die semiconductor device 800 described above with reference to FIG. 8A and FIG. 8B. For example, multi-die semiconductor device 900 may include similar features configured in a similar manner as multi-die semiconductor device 800, including the first die, the second die, hybrid bond layer 240, dielectric interface 241, the plurality of hybrid bonds 242, and a multi-die seal 254 including hybrid-bond die seal 244 surrounding an interior of multi-die semiconductor device 800. Although not shown in FIG. 9A, multi-die semiconductor device 900 may optionally include a plurality of hybrid-bond crack stops 246 located around a perimeter of multi-die semiconductor device 900.

Similar to multi-die semiconductor device 800, multi-die semiconductor device 900 may also include trench 810. FIG. 9B illustrates a top cross-section view of multi-die semiconductor device 800 in accordance with embodiments of the present disclosure. Specifically, FIG. 9B illustrates a top cross-section view of multi-die semiconductor device 900 along cutline 9B illustrated in FIG. 9A. FIG. 9B shows the relationship of the location of trench 810 relative to hybrid-bond die seal 244 for multi-die semiconductor device 900. For simplicity, FIG. 9B omits the plurality of hybrid bonds 242 located in the interior of multi-die semiconductor device 900 and surrounded by trench 810 and hybrid-bond die seal 244. As shown in FIG. 9B, trench 810 forms a ring located along a perimeter of multi-die semiconductor device 800. For example, trench 810 may form a ring located between hybrid-bond die seal 244 and a plurality of hybrid bonds 242 located in an interior area of multi-die semiconductor device 800.

Referring back to FIG. 9A, multi-die seal 254 may include hybrid-bond die seal 244 within hybrid bond layer 240, as well as various metal layers 237, vias 235, and contacts 233 extending in a continuous manner through first die 210 and thus forming a guard ring in first die 210. Thus, in addition to forming a ring located between hybrid-bond die seal 244 and the interior area of multi-die semiconductor device 900, trench 810 may in some embodiments form a ring that is disposed within a metal guard ring of first die 210 and surrounding, from a top view perspective, the internal circuitry of first die 210.

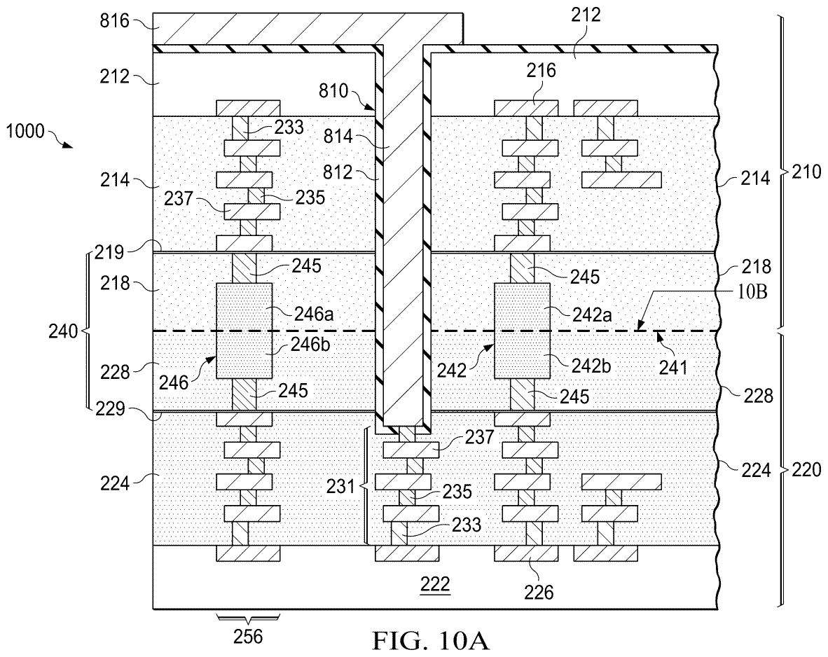

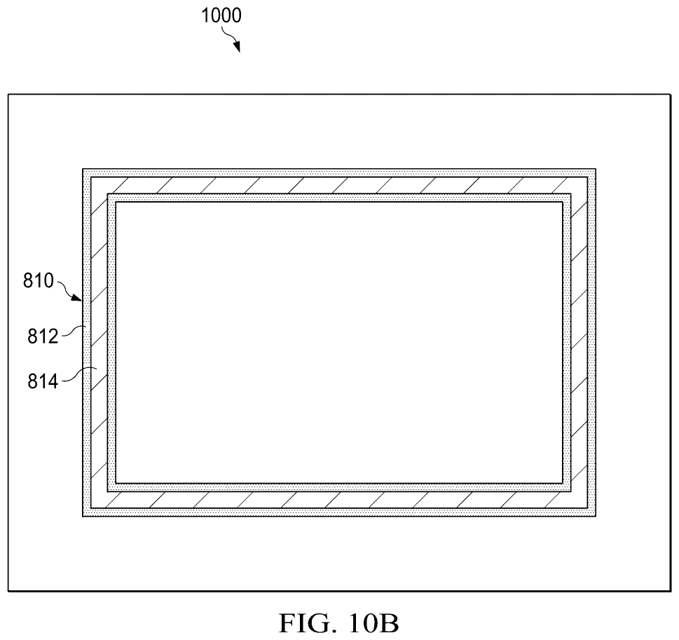

FIG. 10A illustrates a side cross-section view of multi-die semiconductor device 1000 in accordance with embodiments of the present disclosure. FIG. 10B illustrates a top cross-section view of multi-die semiconductor device 800 in accordance with embodiments of the present disclosure. Specifically, FIG. 10B illustrates a top cross-section view of multi-die semiconductor device 1000 along cutline 10B illustrated in FIG. 10A.

Multi-die semiconductor device 1000 may represent an alternative embodiment of multi-die semiconductor device 200 described above with reference to FIGS. 2A and 2B. For example, multi-die semiconductor device 1000 may include similar features configured in a similar manner as multi-die semiconductor device 200, including the first die, the second die, hybrid bond layer 240, dielectric interface 241, the plurality of hybrid bonds 242. Multi-die semiconductor device 1000 may also optionally include a plurality of hybrid-bond crack stops 246 located around a perimeter of multi-die semiconductor device 1000.

As shown in FIG. 10A, multi-die semiconductor device 1000 may also include trench 810. Trench 810 may be formed in a similar manner as described above with reference to FIG. 8A. For example, trench 810 may extend from substrate 212 of first die 210, through dielectric layer 214 of first die 210, through hybrid bond layer 240, and into dielectric layer 224 of second die 220. As also shown in FIG. 10A, second die 220 may include guard ring 231 formed by various metal layers 237, vias 235, and contact 233 extending from the edge of substrate 222 of second die 220 up to an end of trench 810. Trench 810 may be vertically aligned with one or more of the components of guard ring 231. Moreover, the upper-most via 235 may extend through trench liner 812 and couple to trench filler 814. Accordingly, guard ring 231 may be electrically coupled to trench 810, and specifically to trench filler 814 of trench 810, and in turn to a back-side metal shield or a back-side metal grid such as metal grid 816 shown in FIG. 10A.

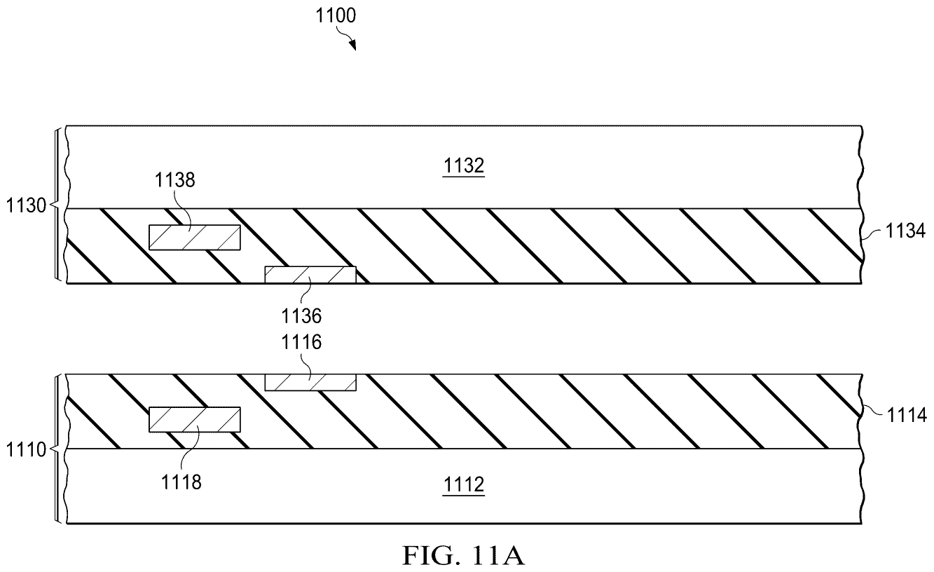

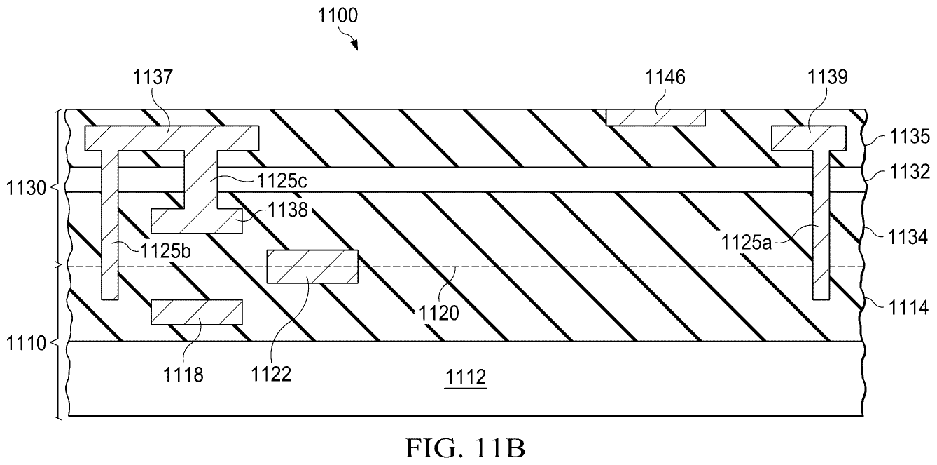

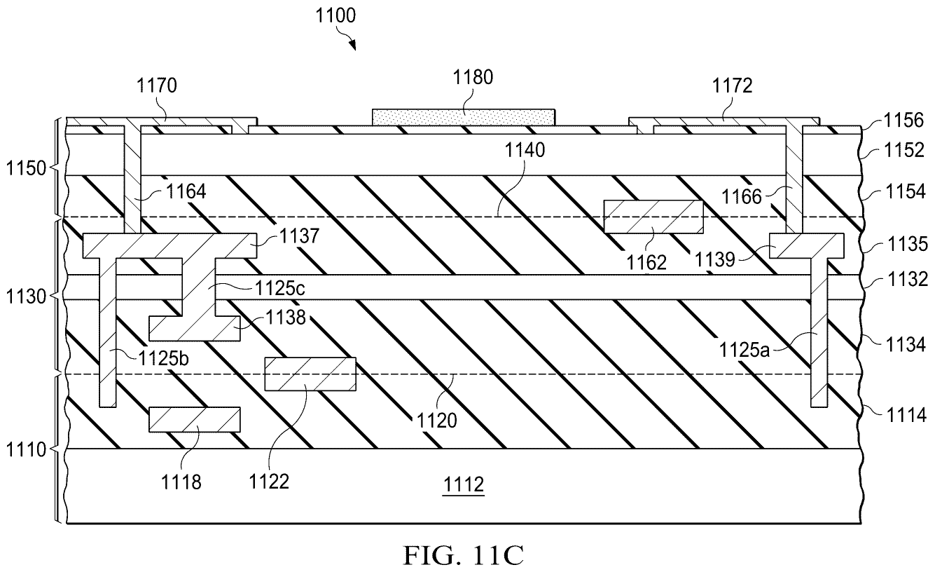

FIGS. 11A-11C illustrate cross-section views of a multi-die stack in accordance with embodiments of the present disclosure. In particular, FIG. 11A and FIG. 11B illustrate intermediate steps during manufacturing of a multi-die stack 1100 shown in FIG. 11C including three dies. As described above, the various die on a wafer will not be separated until after dicing. The various processing steps described below with respect to FIGS. 11A-11C may be performed at the wafer level before dicing. Nonetheless, for the purposes of the present disclosure, the term die may refer to either a pre-diced area of a wafer or a separated die post-dicing.

As shown in FIG. 11A, first die 1110 may be provided. First die 1110 may be, for example, an application specific integrated circuit (ASIC) die, including image-processing circuitry. First die 1110 may include substrate 1112 and dielectric layer 1114. In some embodiments, substrate 1112 may be formed by a semiconductor material such as silicon. Dielectric layer 1114 may include a dielectric material such as silicon dioxide. First die 1110 may include various metal layers, such as metal layer 1118. Metal layer 1118 may include a metal, such as aluminum or copper, or an alloy thereof, or any other metal or alloy suitable for routing electrical signals that may be, for example, sent, received, or processed by, the internal circuitry of first die 1110.

As also shown in FIG. 11A, second die 1130 may be provided. Second die 1130 may be, for example, a sample-and-hold (S/H) die, including circuitry suitable to sample image signals from an image-sensing die, hold those image signals, and pass the image signals to an image processing die such as first die 1110. Second die 1130 may include substrate 1132 and dielectric layer 1134. In some embodiments, substrate 1132 may be formed by a semiconductor material such as silicon. Dielectric layer 1134 may include a dielectric material such as silicon dioxide. Second die 1130 may include various metal layers, such as metal layer 1138. Metal layer 1138 may include a metal, such as aluminum or copper, or an alloy thereof, or any other metal or alloy suitable for routing electrical signals.

As also shown in FIG. 11A, first die 1110 may include pad 1116 disposed in dielectric layer 1114, and second die 1130 may include pad 1136 disposed in dielectric layer 1134. Pad 1116 and pad 1136 may be configured to align. Further, pad 1116 and pad 1136 may comprise the same metal material, for example copper, as each other. The respective surfaces of dielectric layer 1114 and dielectric layer 1134 may be planarized and placed against each other. A first room temperature bond may cause dielectric layer 1114 and dielectric layer 1134 to bond at interface 1120 shown in FIG. 11B. A high-temperature anneal, of for example 150 to 400 degrees Celsius, or any other suitable temperature may then be applied. The copper material of pads 1116 and 1136 may thus expand and fuse together. Upon cooling, the copper material of pads 1116 and 1136 may form hybrid bond 1122 shown in FIG. 11B.

After the bonding of first die 1110 and second die 1130, substrate 1132 may be thinned by a chemical mechanical planarization (CMP) process. In some embodiments, substrate 1132 of second die 1130 may be thinned such that the total remaining thickness of second die 1130 is, for example, 3 μm or less. Further, dielectric layer 1135 may be formed on second die 1130 on the opposite side of substrate 1132 relative to dielectric layer 1134. In conjunction with the formation of dielectric layer 1135, various trenches and/or through-silicon vias (TSVs) may be formed in and through second die 1130 as described below.

As shown in FIG. 11B, trenches 1125a and 1125b may be formed, starting in dielectric layer 1135, extending through substrate 1132, through dielectric layer 1134, past interface 1120, and into dielectric layer 1114 of first die 1110. In some embodiments, trenches 1125a and 1125b may be formed in the same manner as trench 810 described above with reference to FIG. 8A. Thus, although not specifically shown in FIG. 11B and FIG. 11C, trenches 1125a and 1125b may include both a trench liner including a high-K dielectric layer and a conductive trench filler including, for example, a metal or metal alloy such as copper, aluminum, tungsten, or any other suitable metal or metal alloy. As further shown in FIG. 11B, a through-silicon via (TSV) 1125c may be formed in first die 1130, extending from dielectric layer 1135, through substrate 1132, and into dielectric layer 1134, reaching for example the metal routing provided by metal layer 1138. TSV 1125c may be formed in the same manner as trenches 1125a and 1125b, but may be contained within second die 1130. Various redistribution lines (RDLs) may be placed above and in electrical contact with the metal fillers of trenches 1125a and 1125b and TSV 1125c. For example, RDL 1137 may be placed above and in electrical contacts with the metal filler of both trench 1125b and TSV 1125c. Further, RDL 1139 may be placed above and in electrical contact with the metal filler of trench 1125a. The metal fillers of the trenches and TSVs, as well as the RDLs may thus be utilized to electrically ground the trenches for example.

Moving to FIG. 11C, a third die 1150 may be provided and joined to an upper surface of second die at interface 1140. Third die 1150 may be a light-sensing die. For example, third die 1150 may include an array of image pixels, each including one or more photodiodes, in an interior area of the die. Third die 1150 may include dielectric layer 1154 and substrate 1152. Third die 1150 may be bonded to second die 1130 at interface 1140 in a similar manner as described above for bonding first die 1110 to second die 1130 at interface 1120. For example, pad 1146 (shown in FIG. 11B) may include a metal material such as copper, and may be aligned with a similarly configured pad at the surface of dielectric layer 1154 of third die 1150. A room temperature bond may bond dielectric layer 1135 of second die 1130 to dielectric layer 1154 of third die 1150 at interface 1140. Further, an anneal may expand and fuse the copper material of pad 1146 and the corresponding pad for third die 1150. The subsequent cooling of the copper material may form hybrid bond 1162.

After bonding, substrate 1152 may be thinned, for example by a selective etch and/or CMP process. A passivation layer 1156 may then be added to the upper surface of substrate 1152, on the opposite side of substrate 1152 relative to dielectric layer 1154. In some embodiments, passivation layer 1156 may include silicon dioxide. In some embodiments, passivation layer may also or alternatively include a high-K dielectric, such as one or more of hafnium oxide, aluminum oxide, and/or tantalum oxide.

Trench 1164 and trench 1166 may be formed, extending from the upper surface of third die 1150, through passivation layer 1156, through substrate 1152, through dielectric layer 1154, past interface 1140, and in to dielectric layer 1135 of second die 1130. In some embodiments, trench 1164 and trench 1166 may be formed in a similar manner as described above with reference to trench 810 shown in FIG. 8A and trenches 1125a and 1125b shown in FIG. 11B. As shown in FIG. 11C, trench 1164 may extend from backside grid line 1170 to RDL 1137. Likewise, trench 1166 may extend from backside grid line 1172 to RDL 1139. Thus, the metal fillers of trench 1164 and trench 1166 may electrically couple RDL 1137 and RDL 1139 to the backside grid, thereby grounding the backside grid and the respective trenches. Accordingly, trenches 1164 and 1125b, or trenches 1166 and 1125a, may collectively form a multi-layer trench that extends from a back-side surface of a third die (for example a light-sensing die), through the third die, through a second die (for example a S/H die), and into the dielectric layer of a first die (for example, an image processing die).

In some embodiments, a color filter array 1180 may also be applied to the upper surface of passivation layer 1156. Although not shown in FIG. 11C, one or more microlenses may also be formed, for example above color filter array 1180, to direct incident light toward one or more photodiode-based image pixels included in active regions of substrate 1152 of third die 1150.

Although examples have been described above, other modifications and variations may be made from this disclosure without departing from the spirit and scope of these examples. The above descriptions of various embodiments illustrate the principles of the invention. Numerous variations and modifications will become apparent to those skilled in the art based on the above disclosure. The following claims are intended to embrace all such variations and modifications.

What is claimed is:

1. A semiconductor device comprising:
a first die;
a second die; and
a hybrid bond layer bonding the first die and the second die, the hybrid bond layer including:
a plurality of hybrid bonds coupling internal circuitry of the first die to internal circuitry of the second die;
a hybrid-bond die seal surrounding at least in part the plurality of hybrid bonds; and
a plurality of hybrid-bond crack stops located around a perimeter of the semiconductor device between the hybrid-bond die seal and a device edge.

2. The semiconductor device of claim 1, wherein each of the plurality of hybrid-bond crack stops have a same height and a same width as each of the plurality of hybrid bonds.

3. The semiconductor device of claim 1, wherein the plurality of hybrid-bond crack stops have a same minimum pitch as the plurality of hybrid bonds.

4. The semiconductor device of claim 1, wherein the hybrid-bond die seal forms a ring surrounding the plurality of hybrid bonds.

5. The semiconductor device of claim 1, wherein the hybrid-bond die seal includes:
a first linear portion disposed along a first axis;
a second linear portion disposed along a second axis that is orthogonal to the first axis; and
a joint coupling the first linear portion to the second linear portion.

6. The semiconductor device of claim 5, wherein the joint is curved.

7. The semiconductor device of claim 5, wherein:
the joint linearly extends from the first linear portion to the second linear portion;
the joint forms a first interior angle with the first linear portion that is greater than 90 degrees; and
the joint forms a second interior angle with the second linear portion that is greater than 90 degrees.

8. The semiconductor device of claim 5, wherein:
the joint includes a plurality of linear-joint portions coupled in series between the first linear portion and the second linear portion of the hybrid-bond die seal; and
each interior angle formed by the first linear portion, the second linear portion, and the plurality of linear-joint portions is greater than 90 degrees.

9. The semiconductor device of claim 1, wherein the hybrid-bond die seal forms a portion of a multi-die seal extending from a substrate of the first die to a substrate of the second die.

10. The semiconductor device of claim 1, wherein at least one of the plurality of hybrid-bond crack stops forms a portion of a multi-die crack stop extending from a substrate of the first die to a substrate of the second die.

11. The semiconductor device of claim 1, further including a trench extending from a substrate of the first die, through a dielectric layer of the first die, through the hybrid bond layer, and into a dielectric layer of the second die.

12. The semiconductor device of claim 11, wherein the trench forms a ring located along the perimeter of the semiconductor device between the hybrid-bond die seal and the device edge.

13. The semiconductor device of claim 11, wherein the trench forms a ring located between the hybrid-bond die seal and the plurality of hybrid bonds.

14. A semiconductor device comprising:
a first die;
a second die; and
a hybrid bond layer bonding the first die and the second die, the hybrid bond layer including:
a plurality of hybrid bonds coupling internal circuitry of the first die to internal circuitry of the second die; and
a plurality of hybrid-bond crack stops arranged in multiple rows, each of the multiple rows forming a ring along a perimeter of the semiconductor device surrounding the plurality of hybrid bonds.

15. The semiconductor device of claim 14, wherein each of the plurality of hybrid-bond crack stops have a same height and a same width as each of the plurality of hybrid bonds.

16. The semiconductor device of claim 15, wherein the plurality of hybrid-bond crack stops have a same minimum pitch as the plurality of hybrid bonds.

17. The semiconductor device of claim 14, wherein the plurality of hybrid-bond crack stops are arranged within the multiple rows such that any single linear path in the hybrid bond layer from an edge of the semiconductor device to an interior of the semiconductor device is intercepted by at least one of the plurality of hybrid-bond crack stops.

18. An image sensor device comprising:
a first die that is a light-sensing die;
a second die that is a signal-processing die; and
a hybrid bond layer bonding the first die and the second die, the hybrid bond layer including:
a plurality of hybrid bonds coupling internal circuitry of the first die to internal circuitry of the second die;
a hybrid-bond die seal forming a ring surrounding the plurality of hybrid bonds; and
a plurality of hybrid-bond crack stops disposed around a perimeter of the image sensor device between the hybrid-bond die seal and a device edge.

19. The image sensor device of claim 18, wherein the hybrid-bond die seal includes:
a first linear portion disposed along a first axis;
a second linear portion disposed along a second axis that is orthogonal to the first axis; and
an obtuse joint coupling the first linear portion to the second linear portion.

20. The image sensor device of claim 18, wherein:
the hybrid-bond die seal forms a portion of a multi-die seal extending from a substrate of the first die to a substrate of the second die; and
at least one of the plurality of hybrid-bond crack stops forms a portion of a multi-die crack stop extending from the substrate of the first die to the substrate of the second die.
